(19) United States
(12) Patent Application Publication
(10) Pub. No.: US 2020/0350278 A1
(43) Pub. Date: Nov. 5, 2020

(54) HYBRID MOLECULAR BONDING METHOD AND ELECTRONIC CIRCUITS FOR IMPLEMENTING SUCH A METHOD

(71) Applicant: Commissariat à l'Energie Atomique et aux Energies Alternatives, Paris (FR)

(72) Inventor: Laurent MILLET, Grenoble (FR)

(21) Appl. No.: 16/863,809

(22) Filed: Apr. 30, 2020

(30) Foreign Application Priority Data
May 3, 2019 (FR) 1904643

(51) Int. Cl. H01L 23/00; H01L 23/528

(52) U.S. Cl. CPC H01L 24/89; H01L 23/528; H01L 24/05; H01L 2224/80031; H01L 2224/80895; H01L 2224/80896; H01L 2224/08145; H01L 24/08

(57) ABSTRACT

The present disclosure relates to a method of hybrid molecular bonding of a first surface of a first electronic circuit to a second surface of a second electronic circuit. The first electronic circuit includes first conductive pads exposed on the first surface and first conductive tracks exposed on the first surface. The length of each first track is equal to at least five times the width of the first track, the first tracks delivering the reference voltage to the first electronic circuit. The second electronic circuit includes second conductive pads exposed on the second surface and second conductive tracks exposed on the second surface. The length of each second track is equal to at least five times the length of the second track. The method comprises placing into contact the first pads with the second pads and the first tracks with the second tracks.

### FIELD

The present disclosure generally relates to a method of hybrid molecular bonding of electronic circuits and to an electronic circuit enabling to implement such a method.

### BACKGROUND

Hybrid molecular bonding enables to stack electronic circuits on one another with an electric interconnection between them. An example of a method of manufacturing electronic devices comprises forming two integrated circuit wafers, each comprising a surface corresponding to the free surface of an insulating layer having conductive pads flush therewith, and attaching to one another these surfaces by hybrid molecular bonding, placing into contact the conductive pads of the two wafers and the insulating layers of the two wafers. The wafers may then be cut to separate the electronic devices. Other examples comprise attaching by molecular bonding separate integrated circuit chips to an integrated circuit wafer or attaching by molecular bonding an integrated circuit chip to another integrated circuit chip.

The obtaining of a surface state adapted to the carrying out of a molecular bonding generally implies a step of chemical-mechanical planarization of the integrated circuit wafers, also called CMP, which generally combines a chemical and mechanical etching. Such a method may require for the different materials present at the surface of the integrated circuit wafers to be substantially homogeneously distributed. This is why conductive pads of same dimensions, for example, having square or hexagonal shape, substantially homogeneously distributed across the surface, are used, where certain pads are not electrically connected to other elements of the integrated circuit wafer and are only used for the hybrid molecular bonding, which corresponds to lost metal.

### SUMMARY

Thus, an object of an embodiment is to at least partly overcome the disadvantages of previously-described electronic circuit molecular bonding methods.

Another object of an embodiment is for most of, preferably more than 90% of, more preferably all the conductive pads taking part in the molecular bonding to also take part in the transmission of signals or of electric power during the operation of the electronic circuits.

For this purpose, an embodiment provides a first hybrid electronic circuit comprising a first surface, intended to be attached to a second electronic circuit by hybrid molecular bonding, first electrically-conductive pads exposed on the first surface, and first electrically-conductive tracks exposed on the first surface, the length of each first track being equal to at least five times the width of the first track, the first tracks delivering a reference voltage to the first electronic circuit.

An embodiment also provides a method of hybrid bonding of a first surface of a first electronic circuit to a second surface of a second electronic circuit, the first electronic circuit comprising first electrically-conductive pads exposed on the first surface and first electrically-conductive tracks exposed on the first surface, the length of each first track being equal to at least five times the width of the first track, the first tracks delivering the reference voltage to the first electronic circuit, and the second electronic circuit comprising second electrically-conductive pads exposed on the second surface and second electrically-conductive tracks exposed on the second surface, the length of each second track being equal to at least five times the width of the second track, the method comprising placing into contact the first pads with the second pads and the first tracks with the second tracks, the second tracks delivering the reference voltage to second electronic circuit and/or to the first electronic circuit.

According to an embodiment, the first tracks are arranged symmetrically with respect to the second tracks.

According to an embodiment, the width of each first track is equal, to within 10%, to the minimum diameter of the circles containing the cross-sections of the first pads.

According to an embodiment, the first pads and the first tracks are separated by a dielectric material.

According to an embodiment, the first tracks have the same composition as the first pads.

According to an embodiment, the first electronic circuit comprises third electrically-conductive tracks of a lower metallization level than the first tracks, some of which are electrically coupled to the pads, others being electrically coupled to the first tracks.

According to an embodiment, the first surface comprises at least first and second regions, the surface density of first pads in the first region being greater than the surface density of pads in the second region.

According to an embodiment, the first surface comprises at least third and fourth regions, the surface density of first tracks in the third region being greater than the surface density of tracks in the fourth region.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a partial simplified cross-section view of an example of a device comprising two electronic circuits attached by hybrid molecular bonding;

FIG. 2 is a partial simplified top view of one of the electronic circuits of FIG. 1 before the bonding step;

FIG. 3 is a partial simplified cross-section view of an embodiment of a device comprising two electronic circuits attached by hybrid molecular bonding;

FIG. 4 is a partial simplified top view of one of the electronic circuits of FIG. 3 before the bonding step;

FIG. 5 is a view similar to FIG. 4 of one of the electronic circuits before the bonding step of another embodiment of a device comprising two electronic circuits attached by hybrid molecular bonding;

FIG. 6 is a view similar to FIG. 4 of another embodiment of an electronic circuit;

FIG. 7 is a view similar to FIG. 4 of another embodiment of an electronic circuit;

FIG. 8 is a view similar to FIG. 4 of another embodiment of an electronic circuit;

FIG. 9 is a view similar to FIG. 4 of another embodiment of an electronic circuit; and

FIG. 10 is a detail view of FIG. 4 for a variant of the electronic circuit.

### DETAILED DESCRIPTION OF THE PRESENT EMBODIMENTS

Like features have been designated by like references in the various figures. In particular, the structural and/or functional features that are common among the various embodiments may have the same references and may dispose identical structural, dimensional and material properties. For the sake of clarity, only the steps and elements that are useful for an understanding of the embodiments described herein have been illustrated and described in detail.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., unless specified otherwise, it is referred to the orientation of the drawings or to an electronic circuit in a normal position of use. Unless specified otherwise, the expressions “around”, “approximately”, “substantially” and “in the order of” signify within 10%, and preferably within 5%. In the following description, the term “conductive” means electrically conductive and the term “insulating” means electrically insulating.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

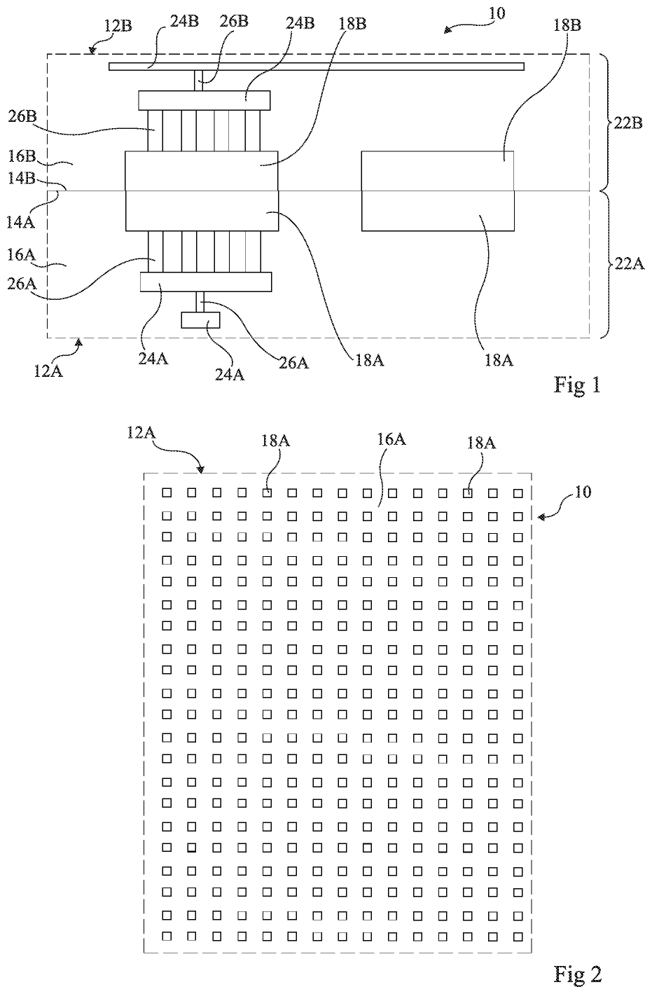

FIG. 1 is a partial simplified cross-section view of an electronic device 10 comprising a first electronic circuit 12A attached to a second electronic circuit 12B and FIG. 2 is a partial simplified top view, at a more reduced scale than FIG. 1, of electronic circuit 12A alone. Electronic circuits 12A, 12B are only partially shown in the drawings. In the rest of the description, an element of electronic circuit 12A is designated with a reference comprising a number followed by suffix “A” and the like element of electronic circuit 12B is designated with a reference comprising a number followed by suffix “B”.

Electronic circuit 12A comprises a surface 14A attached to a surface 14B of electronic circuit 12B by hybrid molecular bonding. Surfaces 14A, 14B are substantially planar. Surface 14A of electronic circuit 12A is delimited by an insulating layer 16A and by conductive pads 18A extending in insulating layer 16A and flush with surface 14A. Similarly, surface 14B of electronic circuit 12B is delimited by an insulating layer 16B and by conductive pads 18B extending in insulating layer 16B and flush with surface 14B Each electronic circuit 12A, 12B may comprise a substrate, not shown, having electronic components, not shown, formed inside and on top of it. The substrate may be covered with a stack 22A, 22B of insulating layers having metal tracks 24A, 24B of different metallization levels and conductive vias 26A, 26B for connecting the electronic components together and connecting them to some of pads 18A, 18B formed therein. Insulating layer 16A, 16B is the insulating layer of stack 22A, 22B located at the top of stack 22A, 22B of insulating layers, opposite to the substrate.

According to an embodiment, electronic circuits 12A, 12B are manufactured separately, in a plurality of items on integrated circuit wafers. The wafers are then attached to each other by molecular bonding, pads 18A being placed into contact with pads 18B and insulating layer 16A being placed into contact with insulating layer 16B. Electronic devices 10 are then obtained by cutting of the bonded integrated circuit wafers.

The obtaining of a surface state adapted to the carrying out of a molecular bonding generally implies a step of chemical-mechanical planarization of the integrated circuit wafers, also called CMP, which generally combines a chemical and mechanical etching. Such a method may require for the different materials present at the surface of the integrated circuit wafers to be substantially homogeneously distributed. Thereby, certain pads 18A, 18B, called dummy pads, may not be connected to vias 26A, 26B, as is the case for the pads 18A and 18B shows on the right-hand side of FIG. 1, and are essentially used to ensure a substantially homogeneous distribution of pads 18A, 18B at the surface of the integrated circuit wafers for the implementation of the planarization method.

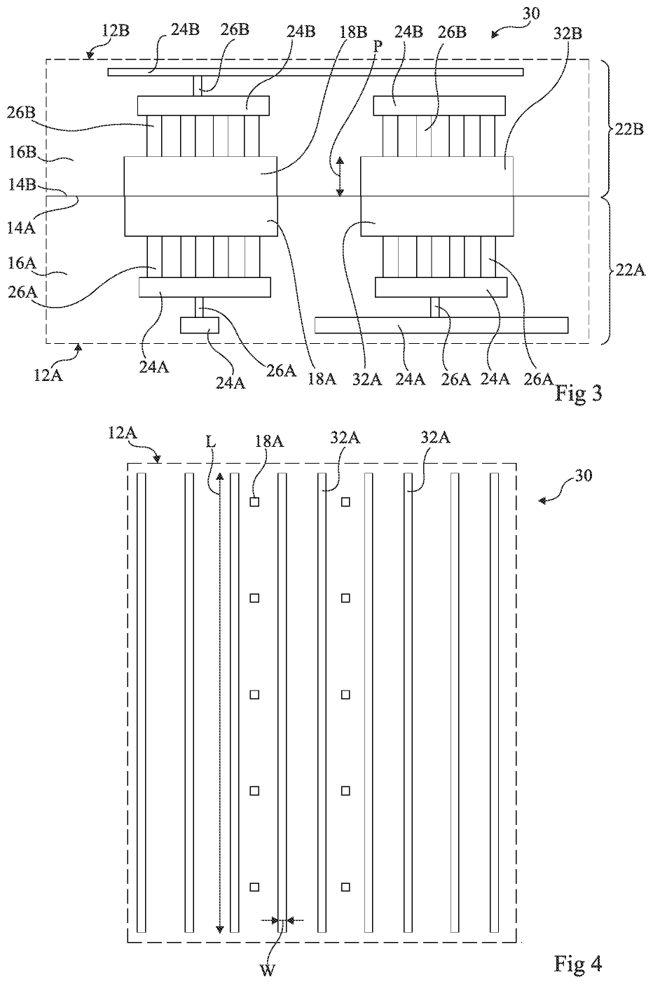

FIGS. 3 and 4 are view similar to FIGS. 1 and 2 respectively of an embodiment of an electronic device 30. Electronic device 30 comprises all the elements of electronic device 10, electronic circuit 12A further comprising conductive tracks 32A flush with surface 14A and electronic circuit 12B further comprising conductive tracks 32B flush with surface 14B. Conductive tracks 32A are in contact with conductive tracks 32B. Conductive tracks 32A, 32B are preferably rectilinear. Conductive tracks 32A, 32B are preferably parallel. According to an embodiment, the width of each conductive track 32A, 32B is substantially equal to the width of a pad 18A, 18B. Conductive tracks 32A, 32B are used to conduct the reference potentials used for the powering of electronic circuits 12A, 12B. As an example, some of conductive tracks 32A, 32B are set to a high reference potential and other conductive tracks 32A, 32B are set to a low reference potential. Thereby, conductive tracks 32A, 32B are connected to conductive vias 26A, 26B to be coupled to metal tracks 24A, 24B of a lower metallization level.

Electronic device 30 comprises few, preferably substantially no, dummy conductive pads. Pads 18A and 18B are preferably used for the transmission of signals other than the power supply potentials. According to an embodiment, at least 90%, preferably at least 95%, of the conductive pads 18A, 18B are connected to conductive vias 26A, 26B in order to be coupled to metal tracks 24A, 24B of a lower metallization level.

Tracks 32A, 32B may be made of a metal or of a metal alloy, particularly copper (Cu), aluminum (Al), titanium (Ti), or tungsten (W). Tracks 32A, 32B may be made of the same conductive material as pads 18A, 18B. Tracks 32A, 32B may be made of a conductive material different from the conductive material forming pads 18A, 18B. Advantageously, tracks 32A, 32B are made of the same material as pads 18A, 18B and are formed simultaneously to pads 18A, 18B. Tracks 32A, 32B may have a monolayer or multilayer structure and for example comprises a stack of at least two metal layers.

Pads 18A, 18B may have, as seen along a direction perpendicular to surface 14A, 14B, a circular, oval, or polygonal, for example, square, rectangular, or hexagonal, cross-section. Preferably, all pads 18A, 18B have the same cross-section. Call D the diameter of the circle containing the cross-section of pad 18A, 18B. When the cross-section of pad 18A is circular, diameter D corresponds to the diameter of the cross-section. Diameter D may be in the range from 0.5 μm to 10 μm. According to an embodiment, the minimum distance between two pads 18A, 18B is greater than or equal to D.

Generally, each track 32A, 32B has, as seen along a direction perpendicular to surface 14A, 14B, a major dimension, called length L, at least five times, preferably at least ten times, greater than a minor dimension, called width W. According to an embodiment, the width W of each track 32A, 32B is equal to D to within 20%, preferably to within 10%, more preferably to within 5%. The depth P of tracks 32A, 32B may be the same as the depth of pads 18A, 18B. Depth P may be in the range from 100 nm to 2μm.

Preferably, the tracks 32A of electronic circuit 12A are arranged symmetrically with respect to the tracks 32B of electronic circuit 12B so that tracks 32A come into contact with tracks 32B during the molecular bonding step. Tracks 32A are then attached to tracks 32B during the molecular bonding step.

According to an embodiment, all the metal surfaces exposed on surface 14A are bonded to metal surfaces exposed on surface 14B. According to an embodiment, the general density of metal, which corresponds to the ratio of the area of the metal surfaces exposed over the entire surface 14A to the general area of surface 14A, is smaller than 50%, preferably between 20% and 25%. Further, for a window corresponding to a square of 100 μm taken at any location on surface 14A, the local density of metal, which corresponds to the ratio of the area of the metal surfaces exposed on the window to the area of the window, is equal to the general density of metal to within 5%, preferably to within 2%. The ratio of the area of tracks 32A to the area of pads 18A may vary from 0% to 90%. This provides a correct bonding after the planarization step, since the relief variations remaining after the planarization step are decreased.

The chemical-mechanical planarization method may cause the obtaining of a surface 14A, 14B before the bonding step, for which pads 18A, 18B and conductive tracks 32A, 32B are slightly recessed with respect to the exposed planar surface of insulating layer 16A, 16B. On placing into contact of electronic circuit 12A with electronic circuit 12B, for example, at room temperature, the molecular bonding occurs first between insulating layer 16A and insulating layer 16B only. An anneal step may then be carried out, for example, at approximately 400° C. This step causes the expansion of pads 18A, 18B and of tracks 32A, 32B so that pads 18A come into contact with pads 18B and pads 32A come into contact with tracks 32B. A molecular bonding is then obtained between pads 18A and pads 18B and between tracks 32A and tracks 32B.

Tracks 32A enable to deliver a general operating voltage, for example, the power supply, to electronic circuit 12A and tracks 32B, bonded to tracks 32A, enable to deliver the same voltage to electronic circuit 12B. In particular, tracks 32A, 32B enable to deliver the reference potentials in the plane of surfaces 14A and 14B over most of, or even over all, integrated circuits 12A, 12B. Tracks 32A, 32B then play the role of a power grid. The vias 26A, 26B connected to tracks 32A, 32B may thus be arranged according to the needs of delivery of the reference potentials. The placement constraints of the vias 26A, 26B connected to tracks 32A, 32B and of the tracks 24B, 24B connected to vias 26A, 26B are thus decreased. In the absence of tracks 32A, 32B, the distribution of the reference potentials should be performed both for electronic circuit 12A and for electronic circuit 12B, by conductive tracks of at least one lower metallization level, the conductive tracks of electronic circuit 12A taking part in the delivery of the reference potentials being connected via pads 18A, 18B to the conductive tracks of electronic circuit 12A taking part in the delivery of the reference potentials. The use of tracks 32A, 32B flush with surfaces 14A, 14B of electronic circuits 12A, 12B for the distribution of the reference potentials may advantageously enable to add a metallization level common to each electronic circuit 12A, 12B. As a variation, tracks 32A, 32B may advantageously come as a support for tracks of another metallization level, already existing and used for the delivery of the general operating voltage to decrease the constraints relative to such tracks. Further, the assembly comprising a track 32A bonded to a track 32B has a low resistance both in the plane of surfaces 14A and 14B and orthogonally to this plane, which is advantageous for the transmission of power supply currents. As a variation, tracks 32A, 32B may be used for the delivery of the general operating voltage only in one of electronic circuit 12A or of electronic circuit 12B.

The number of conductive pads 18A and of tracks 32A depends on the number of signals to be exchanged between electronic circuit 12A and electronic circuit 12B. In the embodiment illustrated in FIG. 4, the number of signals to be exchanged between electronic circuit 12A and electronic circuit 12B is decreased, so that the proportion of tracks 32A in the area of the metal surfaces exposed on surface 14A is much greater than the proportion of pads 18A in the area of the metal surfaces exposed on surface 14A.

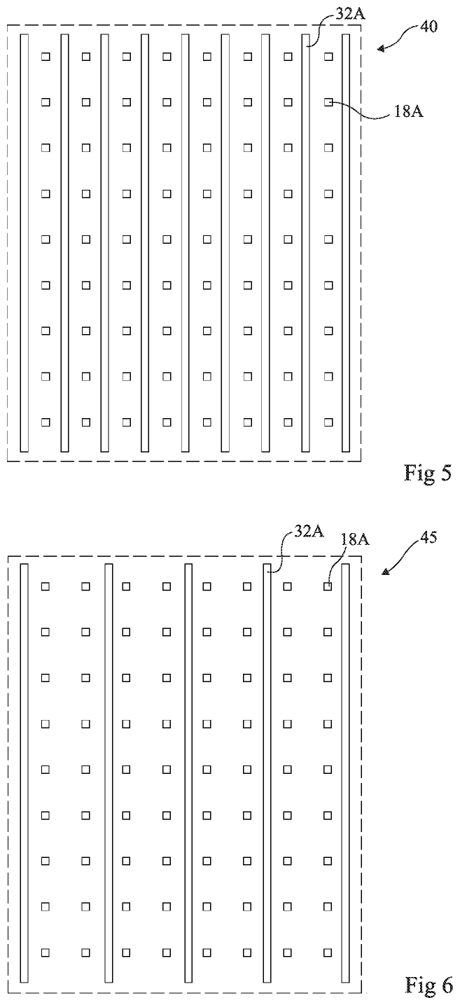

FIG. 5 and FIG. 6 each are a view similar to FIG. 4 of another embodiment of an electronic device 40 and 45. Each electronic device 40 and 45 comprises all the elements of electronic device 30, the proportion of pads 18A in the area of the metal surfaces exposed on surface 14A being greater than that of electronic device 30.

According to an embodiment, the distribution of tracks 32A, 32B is uniform all over electronic circuit 12A, 12B, as for example shown in FIGS. 4, 5, and 6 and/or the distribution of pads 18A, 18B is uniform all over electronic circuit 12A, 12B, as shown in FIGS. 5 and 6. According to another embodiment, the distribution of tracks 32A, 32B is not uniform all over electronic circuit 12A, 12B and/or the distribution of pads 18A, 18B is not uniform all over electronic circuit 12A, 12B. According to an embodiment, surface 14A, 14B comprises at least first and second regions, the surface density of pads 18A in the first region being greater than the surface density of pads 18A in the second region. According to an embodiment, surface 14A, 14B comprises at least third and fourth regions, the surface density of tracks 32A in the third region being greater than the surface density of tracks 32A in the fourth region.

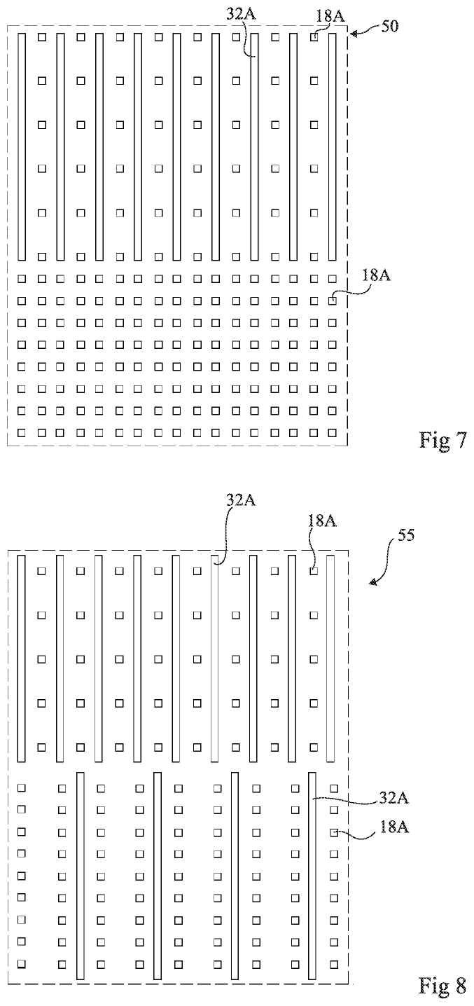

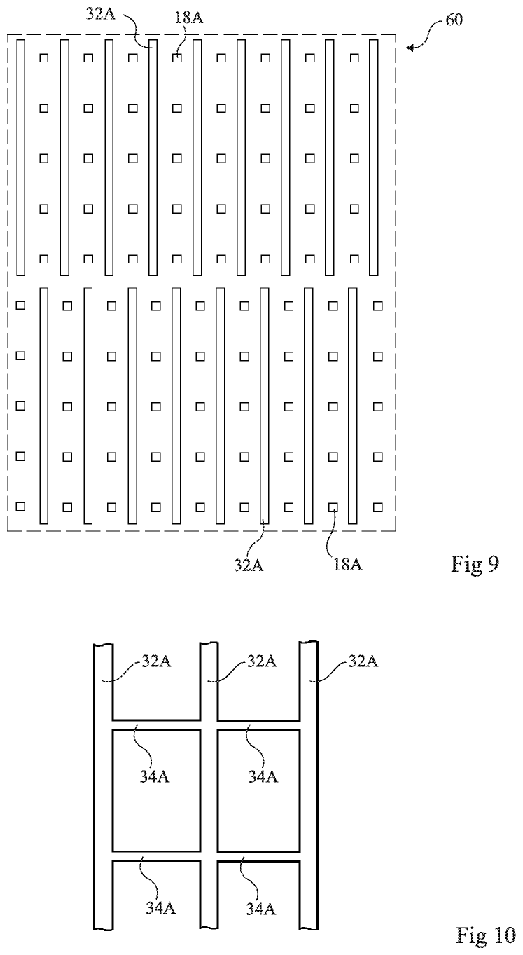

FIGS. 7, 8, and 9 each are a view similar to FIG. 4 of another embodiment of an electronic device 50, 55, 60 for each of which two regions where the distribution of tracks 32A and the distribution of pads 18A are different have been shown.

In the previously-described embodiments, the tracks 32A of electronic circuit 12A are shown as being separate. According to another embodiment, certain tracks 32A may be connected to one another.

FIG. 10 is a detail view of FIG. 4 for a variant of the electronic circuit where three tracks 32A delivering the same reference potential and connected by branches 34A have been shown. Branches 34A may be rectilinear and extend orthogonally to tracks 32A. The width of branches 34A may be equal to or smaller than the width of tracks 32A.

Various embodiments and variants have been described. Those skilled in the art will understand that certain features of these various embodiments and variants may be combined, and other variants will occur to those skilled in the art. In particular, although previously-described embodiments concern an electronic device which comprises the stacking of two electronic circuits, it should be clear that the electronic device may comprise a stack of more than two electronic circuits, and the previously-described embodiments may apply to each interface between two adjacent electronic circuits of the stack.

1. A first electronic circuit comprising a first surface, intended to be attached to a second electronic circuit by hybrid molecular bonding, first electrically-conductive pads exposed on the first surface, and at least three first parallel electrically-conductive tracks exposed on the first surface, first pads being present between each pair of first tracks among the first three tracks, the length of each first track being equal to at least five times the width of the first track, the first tracks delivering a reference voltage to the first electronic circuit.

2. A method of hybrid bonding of a first surface of a first electronic circuit to a second surface of a second electronic circuit, the first electronic circuit comprising first electrically-conductive pads exposed on the first surface and at least three first parallel electrically-conductive tracks exposed on the first surface, first pads being present between each pair of first tracks among the first three tracks, the length of each first track being equal to at least five times the width of the first track, the first tracks delivering a reference voltage to the first electronic circuit and the second electronic circuit comprising second electrically-conductive pads exposed on the second surface and second electrically-conductive tracks exposed on the second surface, the length of each second track being equal to at least five times the width of the second track, the method comprising placing into contact the first pads with the second pads and the first tracks with the second tracks, the second tracks delivering the reference voltage to the second electronic circuit and/or to the first electronic circuit.

3. The method according to claim 2, wherein the first tracks are arranged symmetrically with respect to the second tracks.

4. The method according to claim 2, wherein the width of each first track is equal, to within 10%, to the minimum diameter of the circles containing the cross-sections of the first pads.

5. The method according to claim 2, wherein the first pads and the first tracks are separated by a dielectric material.

6. The method according to claim 2, wherein the first tracks have the same composition as the first pads.

7. The method according to claim 2, wherein the first electronic circuit comprises third electrically-conductive tracks, of a lower metal level than the first tracks, some of which are electrically coupled to the pads, others being electrically coupled to the first tracks.

8. The method according to claim 2, wherein the first surface comprises at least first and second regions, the surface density of first pads in the first region being greater than the surface density of pads in the second region.

9. The method according to claim 2, wherein the first surface comprises at least third and fourth regions, the surface density of first tracks in the third region being greater than the surface density of first tracks in the fourth region.

10. The method according to claim 2, wherein the first electronic circuit comprises a fourth electrically-conductive track, exposed on the first surface and parallel to the first tracks, none of the first pads being present between said fourth track and at least one of the first tracks.

11. The first electronic circuit according to claim 1, wherein the width of each first track is equal, to within 10%, to the minimum diameter of the circles containing the cross-sections of the first pads.

12. The first electronic circuit according to claim 1, wherein the first pads and the first tracks are separated by a dielectric material.

13. The first electronic circuit according to claim 1, wherein me first tracks have the same composition as the first pads.

17. The first electronic circuit according to claim 1, wherein the first electronic circuit comprises third electrically-conductive tracks, of a lower metal level than the first tracks, some of which are electrically couples to the pads, others being electrically coupled to the first tracks.

15. The first electronic circuit according to claim 1, wherein the first surface comprises at least first and second regions, the surface density of first pads in the first region being greater than the surface density of pads in the second region.

16. The first electronic circuit according to claim 1, wherein the first surface comprises at least third and fourth regions, the surface density of first tracks in the third region being greater than the surface density of first tracks in the fourth region.

17. The first electronic circuit according to claim 1, wherein the first electronic circuit comprises a fourth electrically-conductive track, exposed on the first surface and parallel to the first tracks, none of the first pads being present between said fourth track and at least one of the first tracks.
